(19) United States
(12) Patent Application Publication
(10) Pub. No.: US 2021/0026339 A1
(43) Pub. Date: Jan. 28, 2021

(54) INFORMATION PROCESSING DEVICE, DETERMINATION RULE ACQUISITION METHOD, AND COMPUTER-READABLE RECORDING MEDIUM RECORDING DETERMINATION RULE ACQUISITION PROGRAM

(71) Applicant: FUJITSU LIMITED, Kawasaki-shi (JP)

(72) Inventors: Kazunori Maruyama, Zama (JP); Takashi Yamazaki, Kawasaki (JP); Takeshi Soeda, Kawasaki (JP)

(73) Assignee: FUJITSU LIMITED, Kawasaki-shi (JP)

(21) Appl. No.: 17/065,551

(22) Filed: Oct. 8, 2020

Related U.S. Application Data
(63) Continuation of application No. PCT/JP2018/018482, filed on May 14, 2018.

(51) Int. Cl. G05B 19/418; G06N 5/02; G06N 7/00

(52) U.S. Cl. CPC G05B 19/41875; G06N 7/00; G06N 5/025; G05B 19/4183

(57) ABSTRACT

An information processing device includes a processor configured to: calculate a principal component score of each piece of manufacturing data for each verification data by using an eigenvector obtained by performing principal component analysis on each piece of manufacturing data of a manufactured product and performing principal component analysis on each piece of manufacturing data of the verification data to which an OK or no-good label is attached; calculate determination accuracy in a case where OK or no good of each verification data is determined by using a number of dimensions of the principal component score, a combination of the principal component scores for the number of dimensions, and a determination threshold of a distance in a principal component space of the combination; and search for the number of dimensions, the combination, and the determination threshold that make the determination accuracy satisfy a predetermined condition as determination rules.

### CROSS-REFERENCE TO RELATED APPLICATION

This application is a continuation application of International Application PCT/JP2018/018482 filed on May 14, 2018 and designated the U.S., the entire contents of which are incorporated herein by reference.

### FIELD

The embodiment is related to a determination rule acquisition device, a determination rule acquisition method, and a determination rule acquisition program.

### BACKGROUND

Quality of products is managed by performing a performance test on a product before being shipped and determining whether the product is an OK product or no-good product. However, the performance test needs test man-hour and costs such as test equipment costs. Therefore, a technique for determining an abnormality from manufacturing data during manufacturing is disclosed.

Japanese Laid-open Patent Publication No. 2004-165216 is disclosed as related art.

### SUMMARY

According to an aspect of the embodiments, an information processing device includes: a memory; and a processor coupled to the memory and configured to: calculate a principal component score of each piece of manufacturing data for each verification data by using an eigenvector obtained by performing principal component analysis on each piece of manufacturing data of a manufactured product and performing principal component analysis on each piece of manufacturing data of the verification data to which an OK or no-good label is attached; calculate determination accuracy in a case where OK or no good of each verification data is determined by using a number of dimensions of the principal component score, a combination of the principal component scores for the number of dimensions, and a determination threshold of a distance in a principal component space of the combination; and search for the number of dimensions, the combination, and the determination threshold that make the determination accuracy satisfy a predetermined condition as determination rules.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A and 1B are diagrams illustrating a first prediction method;

FIGS. 2A and 2B are diagrams illustrating a second prediction method;

FIG. 3 is a block diagram illustrating an entire configuration of a quality control device according to an embodiment;

FIG. 4 is a block diagram for explaining a hardware configuration of the quality control device;

FIG. 5 is a diagram of a flowchart illustrating entire processing of quality control by the quality control device;

FIG. 6 is a diagram of a flowchart illustrating details of step S1 in FIG. 5;

FIG. 7A is a diagram illustrating learning of an OK/NG determination rule, and FIG. 7B is a diagram illustrating prediction by using the OK/NG determination rule;

FIG. 8 is a diagram of a flowchart illustrating details of step S2 in FIG. 5; and

FIG. 9A is a diagram illustrating normalized manufacturing data, and FIG. 9B is a diagram illustrating prediction accuracy.

### DESCRIPTION OF EMBODIMENTS

For example, the manufacturing data includes data having no correlation with performance test data of a completed product. Therefore, there is a possibility that accuracy of OK/NG determination is lowered. Furthermore, in a case where the number of items of the manufacturing data is large, there is a possibility that search may be local search according to the selected item. Therefore, it is difficult to make prediction with high accuracy.

In one aspect, a determination rule acquisition device, a determination rule acquisition method, and a determination rule acquisition program that can acquire a determination rule with which OK/NG determination can be predicted with high accuracy from manufacturing data may be provided.

Products such as advanced electronic devices are requested to meet quality determined on the basis of specifications. At the time of design, product performance is simulated, and parts that satisfy characteristic specifications set on the basis of the simulation are selected. However, a combination of characteristic variations of a plurality of parts, a variation in a manufacturing process (for example, mounting parts or the like), or the like may affect performance of each product.

Therefore, it is considered to control quality of the product by performing a performance test on a product that has been manufactured and before being shipped and making OK/NG determination whether the product is within a range of the specification (OK) or not (NG). However, the performance test needs test man-hour and costs such as test equipment costs. Therefore, promotion in efficiency of the test is requested. Therefore, if the OK/NG determination can be predicted with high accuracy from a work in process in the middle of manufacturing or a semifinished product, it is sufficient that the performance test is performed on an individual, which has been determined as no good at the time of prediction, after being manufactured, and the efficiency of the test can be achieved.

In a first prediction method, a performance prediction model is constructed by using data of a manufactured product (manufacturing data and performance test data), and OK/NG of a prediction target product is predicted. The manufacturing data includes a plurality of explanatory variables a₁ to aᵢ. For example, the explanatory variables include test data of a part included in the product (output current, output voltage, withstand voltage, resistance value, or the like), test data of a work in process and a semifinished product (output current, output voltage, withstand voltage, resistance value, or the like), an environment in the middle of manufacturing (temperature, humidity, or the like), or the like.

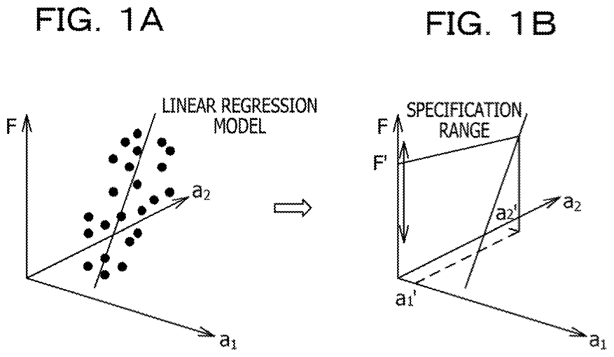

For example, as illustrated in FIG. 1A and the following formula (1), a linear regression model of performance test data F is constructed using the manufacturing data a₁ to aᵢ as the explanatory variables. Next, as illustrated in the following formula (2), a prediction value F of the performance test data is obtained by inputting manufacturing data a₁′ to aᵢ′ of the prediction target product to the linear regression model. Next, as illustrated in FIG. 18, when the prediction value F′ is within a range of specifications, it is determined (predicted) to be OK, and when the prediction value F′ is outside the range of the specifications, it is determined (predicted) to be no good.

F=k₀+k₁·a₁+k₂·a₂+ . . . +kᵢ·aᵢ (1)

F′=k₀+k₁·a₁′+k₂·a₂′+ . . . +kᵢ·aᵢ′ (2)

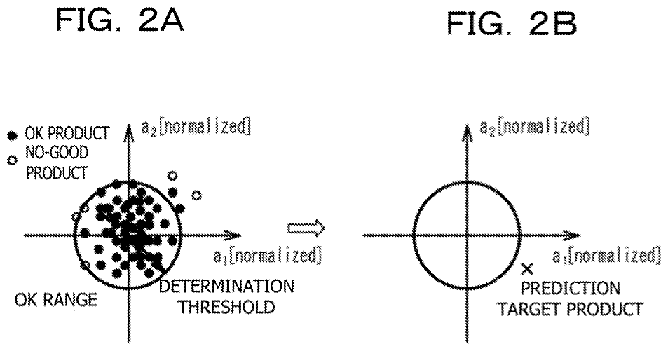

In a second prediction method, it is considered to learn a range in which manufacturing data of the OK product varies by using the data of the manufactured product (manufacturing data and performance test data) and to predict OK/NG of the prediction target product. For example, each explanatory variable of the manufacturing data of the OK product is normalized by using an average value and a standard deviation. Next, as illustrated in FIG. 2A, an OK range is learned from distribution of the OK products and the no-good products in a normalized explanatory variable space. For example, a determination threshold provided at a distance from an origin is learned. The distance in this case may be a simple geometrical distance or may be the Mahalanobis' distance or the like. Next, the manufacturing data of the prediction target product is input, and as illustrated in FIG. 28, OK/NG is determined (predicted) according to whether or not a position in the normalized explanatory variable space is within an OK range.

However, with the first prediction method and the second prediction method, in a case where the manufacturing data does not include an item having high correlation with the performance test data, OK/NG prediction accuracy is lowered. According to the first prediction method described above, it is not possible to construct a linear regression model with high prediction accuracy. According to the second prediction method described above, it is difficult to separate OK and no good in the explanatory variable space. In a case where the number of items in the manufacturing data is significantly large, it is difficult to select an explanatory variable to be used for determination. Furthermore, when the number of combinations of explanatory variables is huge, it is difficult to make combinations in round-robin manner. For example, it is considered to use a stepwise method as a general variable selection method. However, in a case where the number of explanatory variables (manufacturing data item) is significantly large, search is locally made by using the stepwise method. Therefore, the stepwise method is not suitable.

Therefore, in the following embodiment, a determination rule acquisition device, a determination rule acquisition method, and a determination rule acquisition program that can acquire a determination rule with which OK/NG determination can be predicted with high accuracy from manufacturing data will be described. As an example, a determination rule acquisition device, a determination rule acquisition method, and a determination rule acquisition program that can acquire a determination rule with which OK/NG determination can be predicted with high accuracy from the manufacturing data even in a case where the manufacturing data includes significantly large number of items and there is no correlation between the manufacturing data and the OK/NG determination result or between the manufacturing data and the performance test data.

### Embodiment

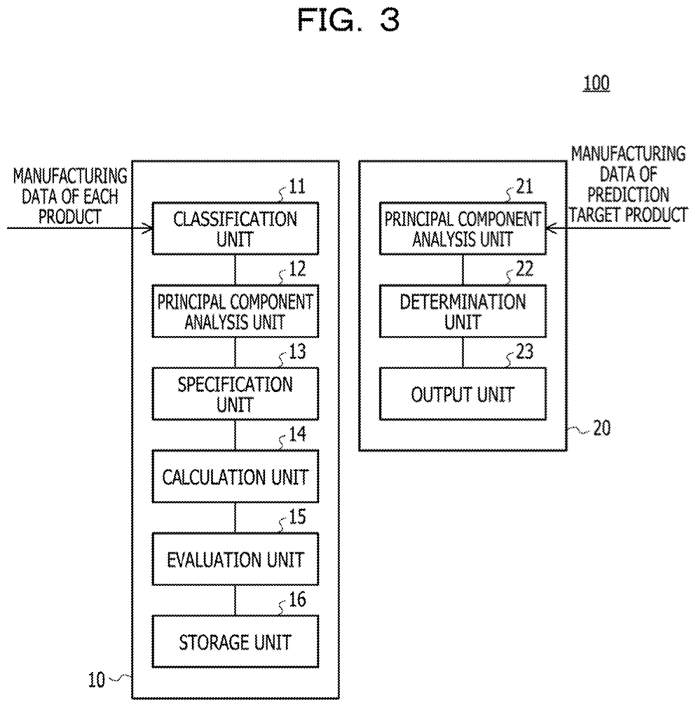

FIG. 3 is a block diagram illustrating an entire configuration of a determination rule acquisition device 100 according to an embodiment. As illustrated in FIG. 3, the determination rule acquisition device 100 includes a determination rule learning unit 10, a prediction unit 20, or the like. The determination rule learning unit 10 includes a classification unit 11, a principal component analysis unit 12, a specification unit 13, a calculation unit 14, an evaluation unit 15, and a storage unit 16. The prediction unit 20 includes a principal component analysis unit 21, a determination unit 22, and an output unit 23.

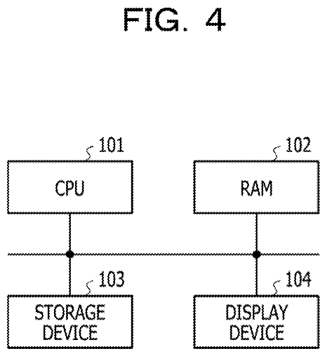

FIG. 4 is a block diagram for explaining a hardware configuration of the determination rule acquisition device 100. As illustrated in FIG. 4, a CPU 101, a RAM 102, a storage device 103, a display device 104, and the like are included. The Central Processing Unit (CPU) 101 serves as a central processing unit. The CPU 101 includes one or more cores. The Random Access Memory (RAM) 102 serves as a volatile memory that temporarily stores a program to be executed by the CPU 101, data to be processed by the CPU 101, and the like. The storage device 103 serves as a non-volatile storage device. Examples of the storage device 103 that can be used include a Read Only Memory (ROM), a solid state drive (SSD) such as a flash memory, a hard disk driven by a hard disk drive, and the like. The storage device 103 stores a determination rule acquisition program. The display device 104 is a device that displays a processing result and is a liquid crystal display or the like. By executing the determination rule acquisition program stored in the storage device 103 by the CPU 101, each unit of the determination rule acquisition device 100 is realized. Note that each unit of the determination rule acquisition device 100 may be hardware such as a dedicated circuit.

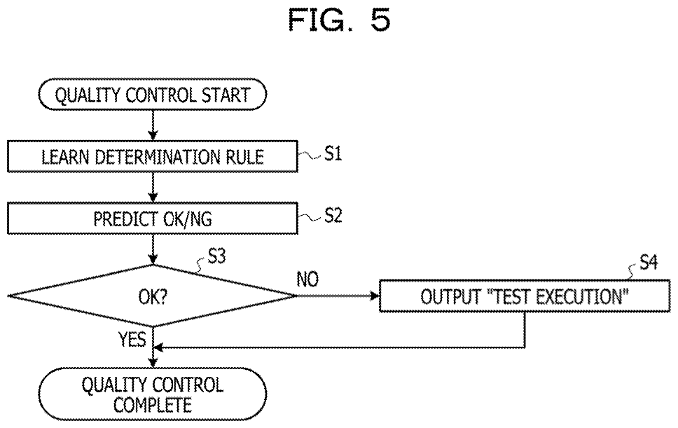

FIG. 5 is a diagram of a flowchart illustrating entire processing of quality control by the determination rule acquisition device 100. As illustrated in FIG. 5, the determination rule learning unit 10 learns an OK/NG determination rule by using manufacturing data of a manufactured product (step S1). Next, the prediction unit 20 predicts OK/NG of the prediction target product by applying the OK/NG determination rule to the manufacturing data of the prediction target product (step S2). Next, the prediction unit 20 determines whether or not a determination result indicates OK (step S3). In a case where it is determined to be “No” in step S3, the prediction unit 20 outputs information regarding performance test execution on the prediction target product (step S4). As a result, a user can grasp a product that needs the performance test, and the performance test is performed on the prediction target product. In a case where it is determined to be “Yes” in step S3, the Information regarding the performance test execution on the prediction target product is not output. Therefore, the performance test on the prediction target product is not performed. According to the above processing, the performance test is performed only on the prediction target product that has been predicted to be no good.

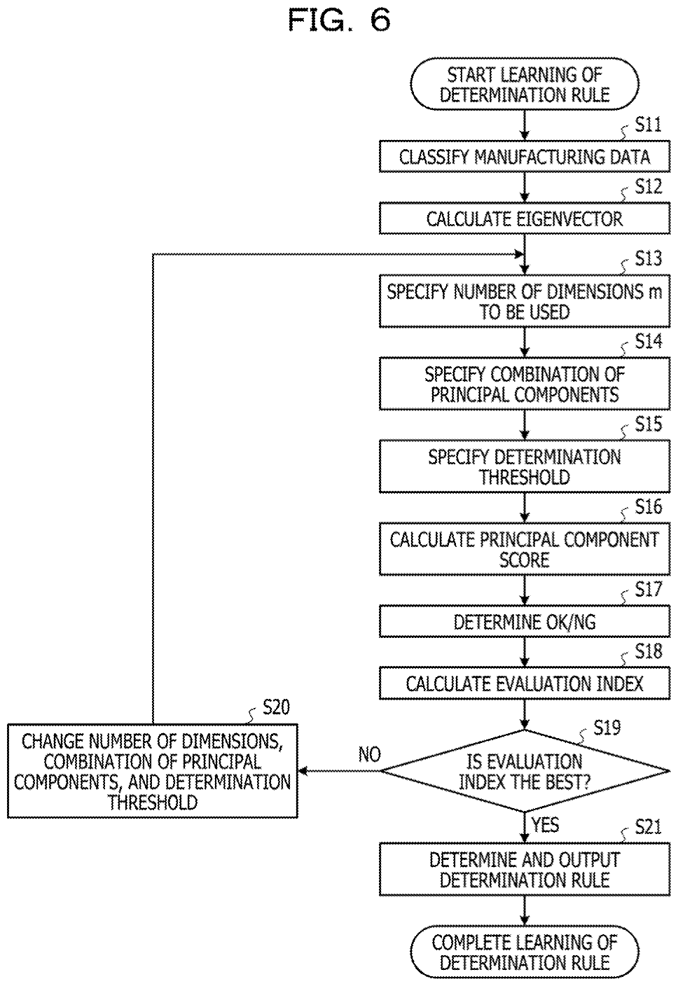

FIG. 6 is a diagram of a flowchart illustrating details of step S1 in FIG. 5. As illustrated in FIG. 6, the classification unit 11 classifies the manufacturing data of the manufactured product into learning data and verification data for each product (step S11). For example, the classification unit 11 classifies the manufacturing data of each product into the learning data and the verification data according to specification information input by the user. Furthermore, the classification unit 11 attaches a label for specifying OK or no good to the learning data and the verification data according to the specification information input by the user.

Next, the principal component analysis unit 12 calculates an eigenvector by performing principal component analysis on each explanatory variable of the learning data (step S12). The eigenvector is stored in the storage unit 16. Next, the specification unit 13 specifies the number of dimensions m used for determination (step S13). The number of dimensions m is the number of principal components selected from among objective variables (principal component scores) that are results of the principal component analysis. Next, the specification unit 13 specifies a combination of the principal components for the number of dimensions specified in step S13 from among all the principal components (step S14). Next, the specification unit 13 specifies a determination threshold regarding a distance in a principal component score space of the specified combination (step S15). The distance here is a distance from the center of gravity in the principal component score space of a product group, to which the label specifying OK is attached, in the learning data. Next, the principal component analysis unit 12 calculates principal component scores (c₁ to cᵢ) by using the eigenvector calculated in step S12 for each verification data (step S16).

Next, the calculation unit 14 performs OK/NG determination on the principal component score calculated in step S16 by using the number of dimensions m, the combination of the principal components for the number of dimensions, and the determination threshold that are specified in steps S13 to S15. The calculation unit 14 calculates determination accuracy of the OK/NG determination (step S17). As the determination accuracy, for example, a correct answer rate can be used. The correct answer rate is a rate at which the verification data to which the OK label is attached is determined to be OK and the verification data to which the no-good label is attached is determined to be no good. Next, the evaluation unit 15 calculates an evaluation index by multiplying a penalty by the determination accuracy calculated in step S17 (step S18). The penalty is a coefficient that monotonically decreases as the number of dimensions m increases and is, for example, 1/m.

Next, the evaluation unit 15 determines whether or not the evaluation index calculated in step S18 is the best (step S19). For example, as an optimization method, an optimal algorithm such as a genetic algorithm, an annealing method, or the like can be used. Alternatively, another predetermined condition such as whether or not the evaluation index calculated in step S18 exceeds a threshold may be used. In a case where it is determined to be “No” in step S19, the evaluation unit 15 instructs the specification unit 13 to change the number of dimensions m, the combination of the principal components, and the determination threshold (step S20). Thereafter, the procedure Is performed from step S13 again. In this case, in steps S13 to S15, the number of dimensions m, the combination of the principal components, and the determination threshold are changed and specified. By repeating steps S13 to S20, an optimal OK/NG determination rule is searched. In a case where it is determined to be “Yes” in step S19, the evaluation unit 15 outputs the number of dimensions m, the combination of the principal components, and the determination threshold specified in steps S13 to S15 as the OK/NG determination rules (step S21). The output OK/NG determination rule is stored in the storage unit 16.

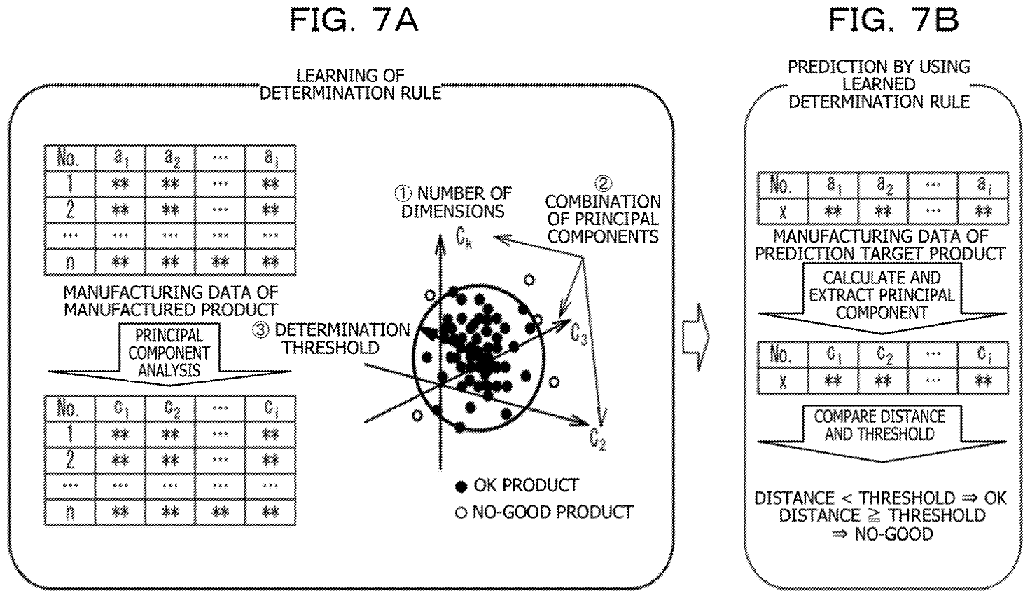

FIG. 7A is a diagram Illustrating learning of the OK/NG determination rule. As illustrated in FIG. 7A, for example, it is assumed that manufacturing data regarding manufactured products 1 to n be obtained as the verification data. The manufacturing data includes explanatory variables a₁ to aᵢ. The principal component analysis is performed on these pieces of verification data by using the eigenvector obtained by performing the principal component analysis on the learning data. According to the analysis, principal component scores of the respective principal components (c₁ to cᵢ) are calculated. From this result, an OK/NG determination rule that satisfies a predetermined condition is searched. For example, as illustrated in the example in FIG. 7A, “the number of dimensions m is three”, “three combinations of the principal components are c₂, c₃, and cₖ”, and “the determination threshold is a radius of a circle” are searched as the OK/NG determination rules.

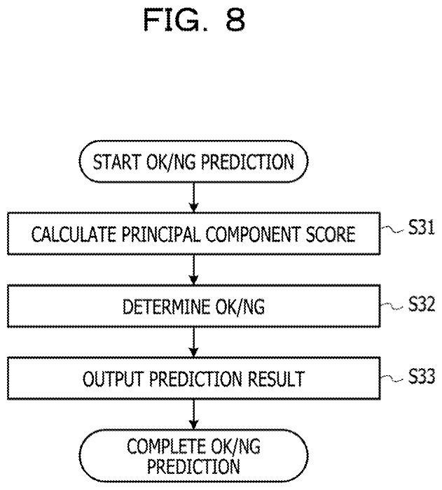

FIG. 8 is a diagram of a flowchart illustrating details of step S2 in FIG. 5. As illustrated in FIG. 8, the principal component analysis unit 21 calculates a principal component score by using the eigenvector stored in the storage unit 16 with respect to the manufacturing data of the prediction target product (step S31). Next, the determination unit 22 performs OK/NG determination on the principal component score calculated in step S31 by using the OK/NG determination rule stored in the storage unit 16 (step S32). The output unit 23 outputs a determination result (prediction result) In step S32 (step S33).

FIG. 7B is a diagram illustrating prediction by using the OK/NG determination rule. For example, as illustrated in FIG. 7B, it is assumed that the manufacturing data (explanatory variables a₁ to aᵢ) of the prediction target product be obtained. The principal component analysis is performed on the manufacturing data of the prediction target product by using the eigenvector obtained by performing the principal component analysis on the learning data. According to the analysis, principal component scores of the respective principal components (c₁ to cᵢ) are calculated. The OK/NG determination rule is applied to this result. For example, when a distance obtained from the combination of the principal components of the number of dimensions m is less than the determination threshold, it is determined to be OK, and when the distance is equal to or more than the determination threshold, it is determined to be no good.

According to the present embodiment, by performing the principal component analysis on each piece of the manufacturing data of the verification data, to which the OK or no-good label is attached, by using the eigenvector obtained by performing the principal component analysis on each piece of the manufacturing data of the learning data, the principal component score of each piece of the manufacturing data is calculated for each verification data. By using the number of dimensions m of the calculated principal component score, a combination of the principal component scores for the number of dimensions, and a determination threshold of a distance in a principal component space of the combination, OK/NG of each verification data is determined, and determination accuracy is calculated. The number of dimensions m, the combination of the principal components for the number of dimensions, and the determination threshold of the distance that make the determination accuracy satisfy a predetermined condition are searched as determination rules. According to this configuration, manufacturing data having high correlation with the determination accuracy is selected. With this selection, a determination rule with which the OK/NG determination can be predicted with high accuracy can be acquired. Furthermore, the OK/NG determination can be predicted with high accuracy by using the acquired determination rule.

It is preferable that the evaluation index obtained by multiplying the determination accuracy described above by the penalty that monotonically decreases as the number of dimensions m increases be calculated and a determination rule that makes the evaluation index satisfy a predetermined condition be searched. In this case, the determination rule is searched so as to decrease the number of dimensions m, and the larger number of dimensions are not selected. As a result, OK/NG can be predicted in a short time.

It is preferable to search for the number of dimensions m that maximizes the evaluation index described above, the combination of the principal component scores for the number of dimensions, and the determination threshold of the distance as the determination rules. In this case, an optimal determination rule can be searched.

Note that, in a case where the correct answer rate is used as an example of the determination accuracy, a correct answer rate of a product to which the no-good label is attached and a correct answer rate of all the products to which the OK label is attached and the no-good label is attached may be calculated, and an OK/NG determination rule that makes the evaluation index satisfy a predetermined condition under a constraint that the correct answer rate of the product to which the no-good label is attached is 100% may be searched. In this case, determination made while missing a no-good product can be suppressed. Therefore, efficiency of a test can be promoted while suppressing an outflow of the no-good products to the market.

### Example

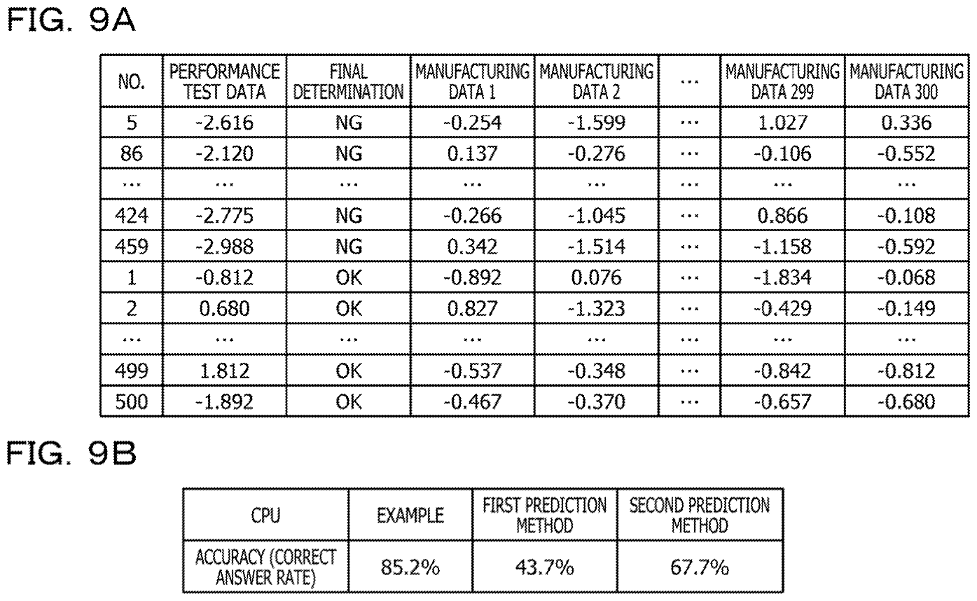

Next, according to the embodiment described above, the optimal OK/NG determination rule has been determined on the basis of actual data. FIG. 9A is a diagram illustrating normalized manufacturing data. In the example in FIG. 9A, manufacturing data of 500 samples (manufactured products) is Illustrated. Furthermore, the number of explanatory variables of the manufacturing data is 300. The number of no-good products of which a determination result of a performance test after being manufactured as a product is 10. In the example in FIG. 9A, a correlation coefficient between the performance test data after being manufactured as a product and the manufacturing data is of −0.2 to 0.2 and is a small value.

The OK/NG determination rule has been determined with respect to the manufacturing data in FIG. 9A according to the embodiment described above. The 500 samples have been classified into 250 pieces of learning data and 250 pieces of verification data. Note that no-good labels have been attached to five samples of the learning data and five samples of the verification data. OK labels have been attached to the remaining samples. Note that the classification has been randomly performed, 10 sets of learning data and verification data using different random sheets have been created, and an average of prediction accuracy (correct answer rate) of 10 times has been calculated. Note that, as a comparative example, the prediction accuracy has been calculated by using the first prediction method described above and the second prediction method described above. In the first prediction method mentioned above, a stepwise method has been used to select variables. In the second prediction method mentioned above, the Mahalanobis' distance has been used, and the stepwise method has been used to select the variables.

FIG. 9B is a diagram illustrating prediction accuracy. As illustrated in FIG. 98, the prediction accuracy has been low with the first prediction method and the second prediction method. Whereas, high prediction accuracy can be obtained by determining the OK/NG determination rule according to the embodiment described above. In this way, a result of realizing the high prediction accuracy can be obtained by determining the OK/NG determination rule according to the embodiment described above.

In the example described above, the principal component analysis unit 12 functions as an example of a principal component analysis unit that calculates a principal component score of each piece of manufacturing data for each verification data by using an eigenvector obtained by performing principal component analysis on each piece of manufacturing data of a manufactured product and performing the principal component analysis on each piece of manufacturing data of the verification data to which an OK or no-good label is attached. The calculation unit 14 functions as an example of a calculation unit that calculates the determination accuracy in a case where OK/NG of each verification data is determined by using the number of dimensions of a principal component score calculated by the principal component analysis unit, a combination of the principal component scores for the number of dimensions, and a determination threshold of a distance in a principal component space of the combination. The specification unit 13 and the evaluation unit 15 function as an example of a search unit that searches for the number of dimensions that makes the determination accuracy satisfy a predetermined condition, the combination, and the determination threshold as determination rules. The prediction unit 20 functions as an example of a prediction unit that predicts OK/NG of a prediction target product by calculating the principal component score by performing the principal component analysis on the manufacturing data of the prediction target product by using the eigenvector and applying the determination rule stored in the storage unit to the calculated principal component score.

The embodiment and the example of the present embodiment have been described in detail. However, the present embodiment is not limited to such a specific embodiment and example, and various modifications and alterations can be made within the scope of gist of the present embodiment described in the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An information processing device comprising:
a memory; and
a processor coupled to the memory and configured to:
calculate a principal component score of each piece of manufacturing data for each verification data by using an eigenvector obtained by performing principal component analysis on each piece of manufacturing data of a manufactured product and performing principal component analysis on each piece of manufacturing data of the verification data to which an OK or no-good label is attached;
calculate determination accuracy in a case where OK or no good of each verification data is determined by using a number of dimensions of the principal component score, a combination of the principal component scores for the number of dimensions, and a determination threshold of a distance in a principal component space of the combination; and
search for the number of dimensions, the combination, and the determination threshold that make the determination accuracy satisfy a predetermined condition as determination rules.

2. The information processing device according to claim 1, wherein
the processor calculates an evaluation index obtained by multiplying the determination accuracy by a penalty that monotonically decreases as the number of dimensions increases and searches for the number of dimensions, the combination, and the determination threshold that make the evaluation index satisfy a predetermined condition.

3. The information processing device according to claim 2, wherein
the processor searches for the number of dimensions, the combination, and the determination threshold that maximize the evaluation index as the determination rules.

4. The information processing device according to claim 1, wherein
the processor searches for the number of dimensions, the combination, and the determination threshold using a condition such that a correct answer rate of OK or no-good determination with respect to the verification data to which the no-good label is attached is 100% as a constraint.

5. The information processing device according to claim 1, wherein:
the processor predicts OK or no good of a prediction target product by calculating a principal component score by performing principal component analysis on manufacturing data of the prediction target product by using the eigenvector and applying the determination rule to the calculated principal component score.

6. A determination rule acquisition method comprising:
calculating, by a computer, a principal component score of each piece of manufacturing data for each verification data by using an eigenvector obtained by performing principal component analysis on each piece of manufacturing data of a manufactured product and performing principal component analysis on each piece of manufacturing data of the verification data to which an OK or no-good label is attached;
calculating determination accuracy in a case where OK or no good of each verification data is determined by using a number of dimensions of the principal component score, a combination of the principal component scores for the number of dimensions, and a determination threshold of a distance in a principal component space of the combination; and
searching for the number of dimensions, the combination, and the determination threshold that make the determination accuracy satisfy a predetermined condition as determination rules.

7. The determination rule acquisition method according to claim 6, further comprising
predicting OK or no good of a prediction target product by calculating a principal component score by performing principal component analysis on manufacturing data of the prediction target product by using the eigenvector and applying the determination rule to the calculated principal component score.

8. The determination rule acquisition method according to claim 7, wherein
a performance test is performed on the prediction target product that is predicted as no good, after manufacturing is completed.

9. A non-transitory computer-readable recording medium having stored therein a determination rule acquisition program for causing a computer to execute processing comprising:
calculating a principal component score of each piece of manufacturing data for each verification data by using an eigenvector obtained by performing principal component analysis on each piece of manufacturing data of a manufactured product and performing principal component analysis on each piece of manufacturing data of the verification data to which an OK or no-good label is attached;
calculating determination accuracy in a case where OK or no good of each verification data is determined by using a number of dimensions of the calculated principal component score, a combination of the principal component scores for the number of dimensions, and a determination threshold of a distance in a principal component space of the combination; and
searching for the number of dimensions, the combination, and the determination threshold that make the determination accuracy satisfy a predetermined condition as determination rules.
